(19) United States
(12) Patent Application Publication
(10) Pub. No.: US 2017/0294271 A1
(43) Pub. Date: Oct. 12, 2017

(54) DYE-SENSITIZED SOLAR PANEL

(71) Applicant: KING SAUD UNIVERSITY, Riyadh (SA)

(72) Inventors: MANAL AHMED GASMELSEED AWAD, RIYADH (SA); AWATIF AHMED HENDI, RIYADH (SA); KHALID MUSTAFA OSMAN ORTASHI, RIYADH (SA); NAWAL AHMAD ABDU MADKHALI, RIYADH (SA); AISHA SALAH BADWELAN, RIYADH (SA)

(21) Appl. No.: 15/097,264

(22) Filed: Apr. 12, 2016

(51) Int. Cl. H01G 9/20; H01L 51/00; H01G 9/00

(52) U.S. Cl. CPC H01G 9/2059; H01G 9/2022; H01G 9/2004; H01G 9/0029; H01G 9/204; H01L 51/0093

(57) ABSTRACT

The dye-sensitized solar panel includes a metal oxide layer and an organic photosensitizing dye on the metal oxide layer. The organic photosensitizing dye is extracted from chard (B. vulgaris subsp. cicla), and the metal oxide layer is composed of zinc oxide nanoparticles synthesized using B. vulgaris subsp. cicla dye as a reducing agent. A working electrode is mounted on a first transparent substrate. The working electrode includes a metal electrode and the metal oxide layer formed thereon. A counter electrode is mounted on a second transparent substrate. An electrolyte is sandwiched between the working electrode and the counter electrode.

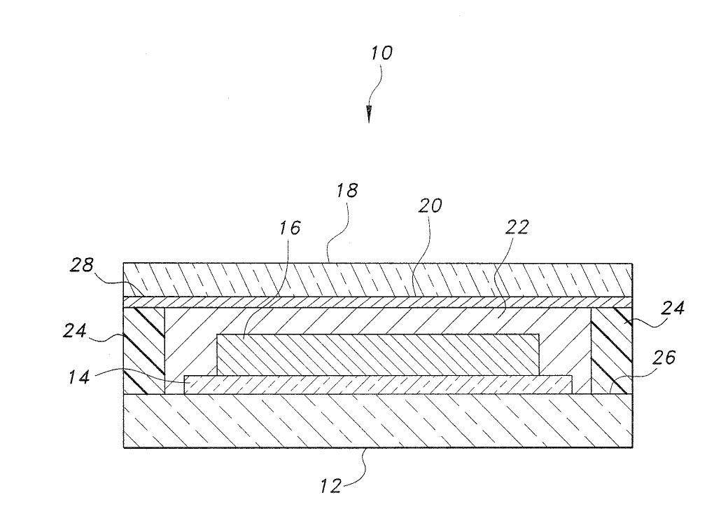

### BACKGROUND OF THE INVENTION

### 1. Field of the Invention

The present invention relates to solar cells, solar panels and the like, and particularly to a dye-sensitized solar panel including an extract of chard (B. vulgaris subsp. cicla).

### 2. Description of the Related Art

A dye-sensitized solar cell (DSSC) is a type of solar cell belonging to the group of thin film solar cells. The dye-sensitized solar cell has a number of attractive features, such as its relatively easy and low-cost manufacture, typically by conventional roll-printing techniques. Most dye-sensitized solar cells are also semi-flexible and semi-transparent, offering a variety of uses which are typically not applicable to glass-based systems.

The performance of the DSSC is mainly based on the dye sensitizer, which acts as an electron pump to transfer the sunlight energy into electron potential. Natural photo-sensitizers have become a viable alternative to expensive and rare organic sensitizers because of their low cost and the abundance of raw materials with no associated environmental threat. Intensive research efforts have been directed toward the application of several highly efficient light-harvesting photosynthetic pigment-protein complexes, including reaction centers, photosystem I (PSI), and photosystem II (PSII), as key components in the light-triggered generation of fuels or electrical power. Thus, a dye-sensitized solar panel with an organic chromophore solving the aforementioned problems is desired.

### SUMMARY OF THE INVENTION

The dye-sensitized solar panel includes a metal oxide layer and an organic photosensitizing dye on the metal oxide layer. The organic photosensitizing dye is extracted from chard (B. vulgaris subsp. cicla), and the metal oxide layer is composed of zinc oxide nanoparticles synthesized using B. vulgaris subsp. cicla dye as a reducing agent. A working electrode is mounted on a first transparent substrate. The working electrode includes a metal electrode and the metal oxide layer formed thereon. A counter electrode is mounted on a second transparent substrate. An electrolyte is sandwiched between the working electrode and the counter electrode.

These and other features of the present invention will become readily apparent upon further review of the following specification and drawing.

### BRIEF DESCRIPTION OF THE DRAWINGS

The sole drawing FIGURE is a side view in section of a dye-sensitized solar panel with an organic chromophore according to the present invention.

Similar reference characters denote corresponding features consistently throughout the attached drawing.

### DETAILED DESCRIPTION OF THE PREFERRED EMBODIMENTS

A dye-sensitized solar panel 10 includes a metal oxide layer and a plant-derived photo-sensitizer supported on the metal oxide layer. The photo-sensitizer can be extracted from chard (B. vulgaris subsp. cicla), and the metal oxide layer includes zinc oxide nanoparticles synthesized using B. vulgaris subsp. cicla extract. As shown in the sole FIGURE, the dye-sensitized solar panel 10 includes first and second transparent substrates 12, 18, respectively, each having opposed inner and outer surfaces. The first and second transparent substrates may be formed from any type of transparent glass or other transparent material, such as fluorine-doped tin oxide, as is well known in the construction of conventional dye-sensitized solar panels.

A working electrode is mounted on the inner surface 26 of the first transparent substrate 12. The working electrode is formed from metal 14 (with a resistance preferably less than 30Ω) and the metal oxide layer 16 formed thereon. The metal oxide layer 16 includes zinc oxide nanoparticles synthesized using B. vulgaris subsp. cicla extract as a reducing agent. A photosensitizer layer is also supported on the metal oxide layer 16 which, as noted above, includes B. vulgaris subsp. cicla dye.

As in a conventional dye-sensitized solar panel, a counter electrode is mounted on the inner surface 28 of the second transparent substrate 18. The counter electrode is preferably in the faun of a metal plate 20 formed on the inner surface 28 of second transparent substrate 18. The metal plate 20 can be coated with a layer of graphite or the like. An electrolyte 22 is sandwiched between the working electrode and the counter electrode, and the panel 10 is preferably sealed with a suitable seal 24, gasket or the like to prevent leakage of the electrolyte 22. The electrolyte may be any suitable type of electrolyte used in the construction of dye-sensitized solar panels, such as lemon juice or the like.

In order to prepare the zinc oxide nanoparticles, 0.1 M of zinc nitrate hexa-hydrate was dissolved in B. vulgaris subsp. cicla extract and constantly stirred at 70° C. until the point of complete dissolution. After complete dissolution of, 0.1 M sodium hydroxide (NaOH) aqueous solution was added under constant high-speed stirring, drop by drop. After complete addition of the sodium hydroxide, the solution was stirred, resulting in a green paste. The paste was dried in an oven at about 400° C., resulting in zinc oxide nanoparticles.

The extract or dye of B. vulgaris subsp. cicla was made by washing half of a conventional sized bag of B. vulgaris subsp. cicla leaves, and then blending the leaves in approximately 200 mL of methanol or water. The leaves were ground in the water for between 5 and 10 minutes until the leaves were thoroughly blended. The blended leaves in the water were then centrifuged at 9,000 rpm for 10 minutes to provide the B. vulgaris subsp. cicla extract or dye. The B. vulgaris subsp. cicla extract or dye is green in color.

### EXAMPLE 1

A control sample was prepared using the zinc oxide nanoparticles synthesized using B. vulgaris subsp. cicla, but without the additional layer of the B. vulgaris subsp. cicla dye supported on the metal oxide layer. The zinc oxide nanoparticles were prepared as a paste in nitric acid and coated on a first transparent substrate formed from fluorine-doped tin oxide (FTO). A metal electrode of resistance less than 30Ω was attached to the inner surface of the first transparent substrate. The paste was left to dry, forming a metal oxide layer. Small drops of lemon juice were then applied as the electrolyte. A metal plate was coated with graphite (obtained from a pencil) to form a counter electrode, which was mounted on the second transparent substrate, also formed from fluorine-doped tin oxide. The two substrates were assembled with coated sides together, but offset so that uncoated glass extends beyond sandwich. The metal electrode did not completely cover the inner surface of the substrate. Seal was applied on all sides to prevent leakage of the electrolyte.

The control solar panel was exposed to light from a 12 volt lamp (emitting a mean intensity of 700 lux) and then tested for current and voltage using a microvolt digital multimeter, such as the Model 177 Microvolt DMM, manufactured by Keithley Instruments, Inc. of Cleveland, Ohio. The solar panel was connected to a series of potentiometers with resistance values ranging from 100Ω to 1000Ω. The microvolt digital multimeter measured current and voltage for each load. The values for current and voltage were calculated and measured for maximum current (Iₘ), maximum voltage (Vₘ), open circuit voltage (V_{oc}), and the short circuit current (I_{sc}), and these values were used to calculate the fill factor (FF) and the overall energy conversion efficiency (η). The conversion efficiency (η) is calculated as

$$η = \frac{{I}_{m} \times {V}_{m}}{input power} \times 100 \% ,$$

and the fill factor (FF) is calculated as

$$F F = \frac{{I}_{m} \times {V}_{m}}{{I}_{sc} \times {V}_{oc}} .$$

For the control sample, the maximum voltage was 0.0244 V, the maximum current was 0.016 A, the short circuit current was 0.14 A, and the open circuit voltage was 0.173 V. Thus, for the control sample without the B. vulgaris subsp. cicla dye supported on the metal oxide layer, the conversion efficiency was 16% and the fill factor was 0.0161.

### EXAMPLE 2

In a second example, a sample solar panel was prepared using zinc oxide nanoparticles synthesized using B. vulgaris subsp. cicla as a reducing agent and with the B. vulgaris subsp. cicla dye supported thereon. The zinc oxide nanoparticles were prepared as a paste in nitric acid and coated on the first transparent substrate, formed from fluorine-doped tin oxide. A metal electrode of resistance less than 30Ω was attached to the inner surface of the first transparent substrate. The paste was left to dry, forming the metal oxide layer. The metal oxide layer was soaked in the B. vulgaris subsp. cicla dye for a period of 24 hours to allow adsorption of the dye onto the metal oxide layer. The structure was then rinsed with ethanol to remove any excess dye and, when dry, small drops of lemon juice were applied as the electrolyte. A metal plate was coated with graphite (obtained from a pencil) to faun the counter electrode, which was mounted on the second transparent substrate, also formed from fluorine-doped tin oxide. The two substrates and were assembled with coated sides together, but offset so that uncoated glass extends beyond sandwich. The metal electrode does not completely cover inner surface. Seal was applied on all sides to prevent leakage of the electrolyte.

The sample solar panel was tested in a manner identical to the control sample of Example 1. For the sample solar panel of Example 2, the maximum voltage was 0.3745 V, the maximum current was 0.026 A, the short circuit current was 0.2 A, and the open circuit voltage was 0.203 V. Thus, for the sample solar panel with the B. vulgaris subsp. cicla chromophore dye supported on the metal oxide layer, the conversion efficiency was 28% and the fill factor was 0.2394.

In each of the above examples, the input power was calculated from the known intensity of the lamp and illuminated area of each solar panel, which was (1×2) cm². From the above, one can see that the energy conversion efficiency is highest (28%) for the metal oxide formed from the zinc oxide nanoparticles synthesized using B. vulgaris subsp. cicla as a reducing agent, with the B. vulgaris subsp. cicla dye supported thereon. This is compared against the 16% conversion efficiency of the control sample, which did not have the additional B. vulgaris subsp. cicla dye supported on the metal oxide layer.

It is to be understood that the present invention is not limited to the embodiments described above, but encompasses any and all embodiments within the scope of the following claims.

We claim:

1. A dye-sensitized solar panel, comprising:
a first transparent substrate having opposed inner and outer surfaces;
a working electrode mounted on the inner surface of the first transparent substrate, the working electrode comprising:
a metal electrode;
a metal oxide layer, said metal oxide layer comprising zinc oxide nanoparticles, the zinc oxide nanoparticles being synthesized using B. vulgaris subsp. cicla extract as a reducing agent; and
an organic photosensitizing dye supported on the metal oxide layer, wherein the organic photosensitizing dye includes B. vulgaris subsp. cicla dye;
a second transparent substrate having opposed inner and outer surfaces;
a counter electrode mounted on the inner surface of the second transparent substrate, the counter electrode comprising a conductive layer; and
an electrolyte sandwiched between the working electrode and the counter electrode.

2. The dye-sensitized solar panel as recited in claim 1, wherein said first and second transparent substrates each comprise fluorine-doped tin oxide.

3. The dye-sensitized solar panel as recited in claim 2, wherein said conductive layer of said counter electrode comprises graphite.

4. The dye-sensitized solar panel as recited in claim 3, wherein said electrolyte comprises lemon juice.

5. A method of making a dye-sensitized solar panel, comprising the steps of:
securing a metal electrode to an inner surface of a first transparent substrate;
coating the first transparent substrate with a metal oxide layer, the metal oxide layer comprising zinc oxide nanoparticles, the zinc oxide nanoparticles being synthesized using B. vulgaris subsp. cicla dye as a reducing agent;
soaking the metal oxide layer in an organic photosensitizing dye to adsorb the organic photosensitizing dye therein, the organic photosensitizing dye comprising B. vulgaris subsp. cicla dye;
mounting a counter electrode to an inner surface of a second transparent substrate; and
sandwiching an electrolyte between the working electrode and the counter electrode.

6. The method of making a dye-sensitized solar panel as recited in claim 5, wherein the step of soaking the metal oxide layer in the organic photosensitizing dye comprises soaking the metal oxide layer in the organic photosensitizing dye for 24 hours.

7. The method of making a dye-sensitized solar panel as recited in claim 6, wherein the step of mounting the counter electrode to the inner surface of the second transparent substrate comprises mounting a graphite layer to the inner surface of the second transparent substrate.

8. The method of making a dye-sensitized solar panel as recited in claim 7, wherein the step of sandwiching the electrolyte between the working electrode and the counter electrode comprises sandwiching lemon juice between the working electrode and the counter electrode.

9. The method of making a dye-sensitized solar panel as recited in claim 5, further comprising the steps of:
blending leaves of B. vulgaris subsp. cicla in water;
centrifuging the blended leaves of B. vulgaris subsp. cicla in the water to provide the B. vulgaris subsp. cicla dye.

10. The method of making a dye-sensitized solar panel as recited in claim 5, further comprising the steps of:
blending leaves of B. vulgaris subsp. cicla in methanol;
centrifuging the blended leaves of B. vulgaris subsp. cicla in the water to provide the B. vulgaris subsp. cicla dye.
